(19) United States
(12) Patent Application Publication
(10) Pub. No.: US 2025/0109521 A1
(43) Pub. Date: Apr. 3, 2025

(54) METHOD AND APPARATUS FOR DIAMETER MEASUREMENT OF CZOCHRALSKI MONOCRYSTALLINE SILICON, AND DEVICE FOR GROWING CZOCHRALSKI MONOCRYSTALLINE SILICON

(71) Applicant: Zing Semiconductor Corporation, Shanghai (CN)

(72) Inventors: Kwanghun KIM, Shanghai (CN); Yinfeng LI, Shanghai (CN); Jiawei LI, Shanghai (CN); Xuliang ZHAO, Shanghai (CN)

(73) Assignee: Zing Semiconductor Corporation, Shanghai (CN)

(21) Appl. No.: 18/895,304

(22) Filed: Sep. 24, 2024

(30) Foreign Application Priority Data
Sep. 28, 2023 (CN) 202311283865.9

(51) Int. Cl. C30B 15/26; C30B 29/06; C30B 35/00

(52) U.S. Cl. CPC C30B 15/26; C30B 29/06; C30B 35/00

(57) ABSTRACT

The present application provides a method and an apparatus for measuring ingot diameter, and a device for growing the ingot. The method comprises controlling a first calibration light source and a second calibration light source to emit light; obtaining coordinates of the calibration light sources; obtaining a diameter measurement coefficient based on the coordinates; obtaining diameter coordinates of two ends of the ingot diameter; and obtaining a measured value of the diameter based on the diameter coordinates and the diameter measurement coefficient. Accordingly, the measurement error of the ingot diameter can be reduced, and the accuracy of ingot diameter control during the growth process can be improved, thereby the production efficiency of Czochralski silicon ingot can be increased.

### BACKGROUND OF THE INVENTION

### 1. Field of the Invention

The present invention relates to the semiconductor technical field, and more particularly to a method for measuring a diameter of Czochralski monocrystalline silicon ingot.

### 2. Description of the Related Art

With the rapid development of semiconductor industry, the more strict requirements for monocrystalline materials are requested by semiconductor manufacturers. Generally, the large-capacity crystal pulling furnace with Czochralski process is applied for the growth of monocrystalline silicon ingots. In the process, during the growth of the monocrystalline silicon ingot, accuracy of measurement of ingot diameter is critical for ensuring the growth stability. It is also a core element for ensuring crystal quality and yield.

Conventionally, in the diameter measurement for Czochralski monocrystalline silicon, the charge coupled device (CCD) camera is applied to detect the crystal diameter. During the crystal pulling, due to the shaking caused by crystal rotation and the change of detection angle, the measurement accuracy for crystal diameter by using single set of CCD cameras is low. As such, the crystal pulling efficiency is poor.

### SUMMARY

The purpose of the present application is to provide a method for diameter measurement of Czochralski monocrystalline silicon with reduced measurement error and improved accuracy of ingot diameter control. The method comprises: Step 101: controlling a first calibration light source and a second calibration light source to emit light, wherein the first calibration light source and the second calibration light source have a first distance therebetween, an absolute value of a difference between the first distance and a predetermined ingot diameter is less than a predetermined threshold, and a line connecting the first calibration light source and the second calibration light source has a midpoint located at center of a cross section perpendicular to axial direction of the ingot during the ingot growth; Step 102: obtaining a first coordinate of the first calibration light source based on a first measuring device, obtaining a second coordinate of the second calibration light source based on a second measuring device, wherein the first measuring device and the second measuring device have a distance therebetween equal to the predetermined ingot diameter; Step 103: obtaining a diameter measurement coefficient based on the first coordinate, the second coordinate and the first distance; Step 104: obtaining a first diameter coordinate of one end of the ingot diameter by the first measuring device, and obtaining a second diameter coordinate of the other end of the ingot diameter by the second measuring device; and Step 105: obtaining a measured value of the ingot diameter based on the first diameter coordinate, the second diameter coordinate and the diameter measurement coefficient.

The present application also provides an apparatus for diameter measurement of Czochralski monocrystalline silicon comprising a first measuring device, a second measuring device and a calibration device, wherein the first measuring device and the second measuring device have a distance therebetween equal to a predetermined ingot diameter, the first measuring device is to obtain a first coordinate of a first calibration light source of the calibration device, and the second measuring device is to obtain a second coordinate of a second calibration light source of the calibration device; the calibration device comprises the first calibration light source and the second calibration light source, wherein the first calibration light source and the second calibration light source have a first distance therebetween, an absolute value of a difference between the first distance and the predetermined ingot diameter is less than a predetermined threshold, and a line connecting the first calibration light source and the second calibration light source has a midpoint located at center of a cross section perpendicular to axial direction of the ingot during the ingot growth.

The present application further provides a device for growing Czochralski monocrystalline silicon comprising the diameter measurement apparatus as described above.

### BRIEF DESCRIPTION OF THE DRAWINGS

FIG. 1 shows, in accordance with one embodiment of the present application, a flow chart of the method for diameter measurement of Czochralski monocrystalline silicon.

FIG. 2 shows, in accordance with one embodiment of the present application, the calibration for diameter measurement of Czochralski monocrystalline silicon.

FIG. 3 shows, in accordance with one embodiment of the present application, the measurement of diameter of Czochralski monocrystalline silicon.

FIG. 4 shows, in accordance with one embodiment of the present application, the structure of an apparatus for diameter measurement of Czochralski monocrystalline silicon.

### DETAILED DESCRIPTION OF THE EMBODIMENTS

In the summary of the invention, a series of concepts in a simplified form is introduced, which will be described in further detail in the detailed description. This summary of the present invention does not intend to limit the key elements or the essential technical features of the claimed technical solutions, nor intend to limit the scope of the claimed technical solution.

The present application provides a method for diameter measurement of Czochralski monocrystalline silicon comprising:
Step 101: controlling a first calibration light source and a second calibration light source to emit light, wherein the first calibration light source and the second calibration light source have a first distance therebetween, an absolute value of a difference between the first distance and a predetermined ingot diameter is less than a predetermined threshold, and a line connecting the first calibration light source and the second calibration light source has a midpoint located at center of a cross section perpendicular to axial direction of the ingot during the ingot growth;
Step 102: obtaining a first coordinate of the first calibration light source based on a first measuring device, obtaining a second coordinate of the second calibration light source based on a second measuring device, wherein the first measuring device and the second measuring device have a distance therebetween equal to the predetermined ingot diameter;
Step 103: obtaining a diameter measurement coefficient based on the first coordinate, the second coordinate and the first distance;
Step 104: obtaining a first diameter coordinate of one end of the ingot diameter by the first measuring device, and obtaining a second diameter coordinate of the other end of the ingot diameter by the second measuring device; and
Step 105: obtaining a measured value of the ingot diameter based on the first diameter coordinate, the second diameter coordinate and the diameter measurement coefficient.

In one embodiment, the method further comprises: setting one or plural sets of the first calibration light source and the second calibration light source, and obtaining the diameter measurement coefficient based on the one or plural sets of the first calibration light source and the second calibration light source.

In one embodiment, the method further comprises: controlling a first set of the plural sets of the first calibration light source and the second calibration light source to emit light; obtaining a first coordinate of the first calibration light source in the first set based on the first measuring device, and obtaining a second coordinate of the second calibration light source in the first set based on the second measuring device; obtaining a first diameter measurement coefficient based on the first coordinate, the second coordinate, and the first distance between the first calibration light source and the second calibration light source in the first set; controlling a second set of the plural sets of the first calibration light source and the second calibration light source to emit light; obtaining a third coordinate of the first calibration light source in the second set based on the first measuring device, and obtaining a fourth coordinate of the second calibration light source in the second set based on the second measuring device; obtaining a second diameter measurement coefficient based on the third coordinate, the fourth coordinate, and a second distance between the first calibration light source and the second calibration light source in the second set; repeating the above steps to obtain plural diameter measurement coefficients relative to the plural sets of the first calibration light source and the second calibration light source; and obtaining the diameter measurement coefficient based on the plural diameter measurement coefficients.

In one embodiment, for the Step 103, i.e. the step of obtaining a diameter measurement coefficient based on the first coordinate, the second coordinate and the first distance, the diameter measurement coefficient is equal to the product of the first distance and the reciprocal of the absolute value of the difference between the first coordinate and the second coordinate.

In one embodiment, for the Step 105, the measured value of the ingot diameter is equal to the product of the diameter measurement coefficient and the absolute value of the difference between the first diameter coordinate and the second diameter coordinate.

In one embodiment, the method further comprises: obtaining an actual value of the ingot diameter after the ingot growth; obtaining an actual diameter measurement coefficient based on the first diameter coordinate, the second diameter coordinate, and the actual value of the ingot diameter; and, while a difference between the actual diameter measurement coefficient and the diameter measurement coefficient obtained from the Step 103 is more than the predetermined coefficient threshold, applying the actual diameter measurement coefficient to update the diameter measurement coefficient.

In one embodiment, in the step of obtaining an actual diameter measurement coefficient based on the first diameter coordinate, the second diameter coordinate, and the actual value of the ingot diameter, the actual diameter measurement coefficient is equal to the product of the actual value of the ingot diameter and the reciprocal of the absolute value of the difference between the first diameter coordinate and the second diameter coordinate.

The present application also provides an apparatus for diameter measurement of Czochralski monocrystalline silicon comprising a first measuring device, a second measuring device and a calibration device, wherein the first measuring device and the second measuring device have a distance therebetween equal to a predetermined ingot diameter, the first measuring device is to obtain a first coordinate of a first calibration light source of the calibration device, and the second measuring device is to obtain a second coordinate of a second calibration light source of the calibration device; and the calibration device comprises the first calibration light source and the second calibration light source, the first calibration light source and the second calibration light source have a first distance therebetween, an absolute value of a difference between the first distance and the predetermined ingot diameter is less than a predetermined threshold, and a line connecting the first calibration light source and the second calibration light source has a midpoint located at center of a cross section perpendicular to axial direction of the ingot during the ingot growth.

In one embodiment, the first measuring device has a measuring direction parallel to that of the second measuring device. In one embodiment, the line connecting the first measuring device and the second measuring device is perpendicular to axial direction of the ingot during the ingot growth.

In one embodiment, the apparatus further comprises a guide rail. In one embodiment, the guide rail is perpendicular to the axial direction of the ingot during the ingot growth. The first measuring device and the second measuring device are arranged on the guide rail. The first measuring device and the second measuring device are movable along with the guide rail.

In one embodiment, the first measuring device and the second measuring device comprise a charge coupled device (CCD) camera.

In one embodiment, the calibration device comprises one or plural sets of the first calibration light source and the second calibration light source.

The present application further provides a device for growing Czochralski monocrystalline silicon ingot comprising an apparatus of any of the above described apparatuses.

The method for measuring the diameter of the monocrystalline silicon ingot produced by using Czochralski process is conducted by controlling the first calibration light source and the second calibration light source to emit light, obtaining the first and second coordinates of the first and second calibration light sources by using the first and second measuring devices, respectively; obtaining the diameter measurement coefficient based on the above coordinates and the first distance; during the ingot growth, obtaining the first diameter coordinate of one end of the ingot diameter by using the first measuring device, and obtaining the second diameter coordinate of the other end of the ingot diameter by using the second measuring device; obtaining the measured value of the ingot diameter based on the first diameter coordinate, the second diameter coordinate and the diameter measurement coefficient. Accordingly, the measurement error of the diameter of the Czochralski monocrystalline silicon ingot can be reduced, and the accuracy of control of the ingot diameter during the crystal growth process can be improved, thereby the production efficiency of the monocrystalline silicon can be increased.

### Examples

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

It should be understood that the present invention may be practiced in different forms and that neither should be construed to limit the scope of the disclosed examples. On the contrary, the examples are provided to achieve a full and complete disclosure and make those skilled in the art fully receive the scope of the present invention. In the drawings, for clarity purpose, the size and the relative size of layers and areas may be exaggerated. In the drawings, same reference number indicates same element.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

For a thorough understanding of the present invention, the detailed steps will be set forth in detail in the following description in order to explain the technical solution of the present invention. The preferred embodiments of the present invention is described in detail as follows, however, in addition to the detailed description, the present invention also may have other embodiments.

The present application provides a method for diameter measurement of Czochralski monocrystalline silicon.

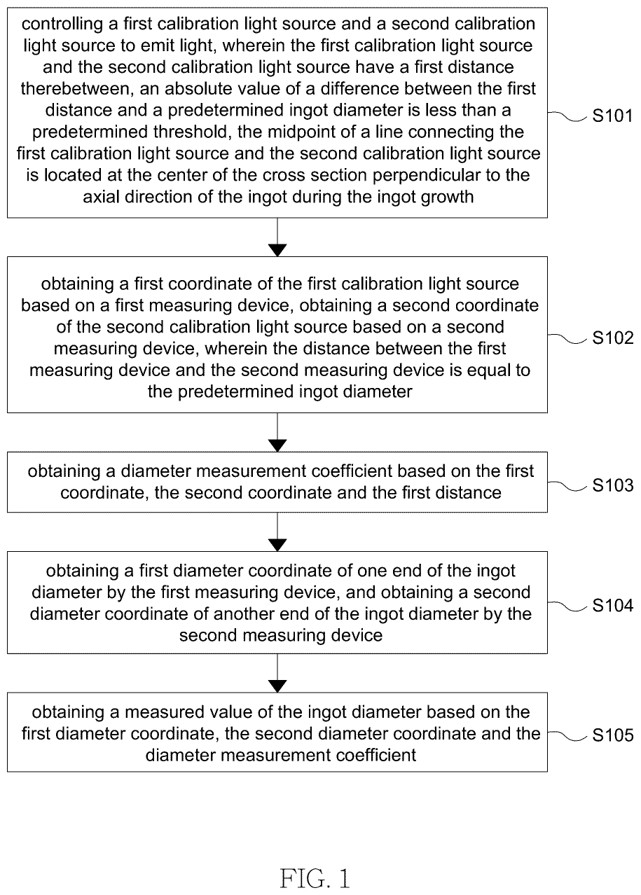

FIG. 1 shows, in accordance with one embodiment of the present application, a flow chart of the method comprising the following steps.

Step S101: controlling a first calibration light source and a second calibration light source to emit light. In one embodiment, the first calibration light source and the second calibration light source have a first distance therebetween. The absolute value of the difference between the first distance and a predetermined ingot diameter is less than a predetermined threshold. The line connecting the first calibration light source and the second calibration light source has a midpoint located at center of a cross section perpendicular to axial direction of the ingot during the ingot growth.

Step S102: obtaining a first coordinate of the first calibration light source based on a first measuring device, and obtaining a second coordinate of the second calibration light source based on a second measuring device. In one embodiment, the distance between the first measuring device and the second measuring device is equal to the predetermined ingot diameter.

Step S103: obtaining a diameter measurement coefficient based on the first coordinate, the second coordinate and the first distance.

Step S104: obtaining a first diameter coordinate of one end of the ingot diameter by the first measuring device, and obtaining a second diameter coordinate of the other end of the ingot diameter by the second measuring device.

Step S105: obtaining a measured value of the ingot diameter based on the first diameter coordinate, the second diameter coordinate and the diameter measurement coefficient.

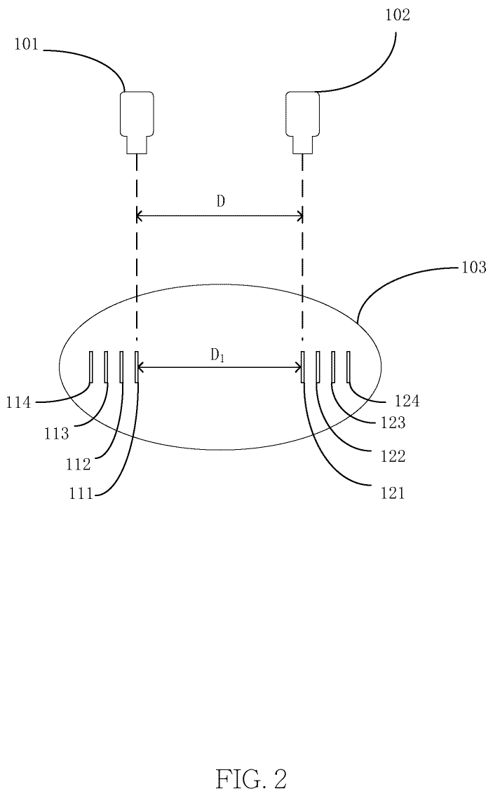

Firstly, the step S101 is conducted. Referring FIG. 2, the first calibration light source 111 and the second calibration light source 121 are controlled to emit light. The first calibration light source 111 and the second calibration light source 121 are spaced with a first distance D₁, in which the absolute value of the difference between the first distance D₁ and the predetermined ingot diameter is less than a predetermined threshold. The line connecting the first calibration light source 111 and the second calibration light source 121 has a midpoint located at the center of a cross section perpendicular to the axial direction of the ingot during the ingot growth.

In one embodiment, the predetermined threshold ranges from 3% to 6% of the predetermined ingot diameter. The distance between the first calibration light source 111 and the second calibration light source 121 is close to the predetermined ingot diameter. In one embodiment, during the ingot growth, the ingot has a cross section perpendicular to the axial direction of the ingot. The cross section of the ingot has a diameter. In one embodiment, the first calibration light source 111 is located at one end of the diameter of the cross section, and the second calibration light source 121 is located at the other end of the diameter. The first calibration light source 111 and the second calibration light source 121 are applied to simulate the two opposite ends of the diameter of the cross section perpendicular to the axial direction of the ingot during the growth process.

In one embodiment, the method further comprises: setting one or plural sets of the first calibration light source and the second calibration light source, and obtaining the diameter measurement coefficient based on the one or plural sets of the first calibration light source and the second calibration light source.

In one embodiment, as shown in FIG. 2, one set or plural sets of calibration light sources are set, which can be a first set including the first calibration light source 111 and the second calibration light source 121, a second set including the first calibration light source 112 and the second calibration light source 122, a third set including the first calibration light source 113 and the second calibration light source 123, a fourth set including the first calibration light source 114 and the second calibration light source 124. In one embodiment, in the first set, the first calibration light source 111 and the second calibration light source 121 have a first distance D₁ therebetween. In the second set, the first calibration light source 112 and the second calibration light source 122 have a second distance D₂ therebetween. In the third set, the first calibration light source 113 and the second calibration light source 123 have a third distance D₃ therebetween. In the fourth set, the first calibration light source 114 and the second calibration light source 124 have a first distance D₄ therebetween. The first distance D₁, the second distance D₂, the third distance D₃, and the fourth distance D₄ meet the condition that the absolute value of the difference between the distance and the predetermined ingot diameter is less than a predetermined threshold.

Then the step S102 is conducted. Referring FIG. 2, a first coordinate of the first calibration light source 111 based on a first measuring device 101 is obtained. A second coordinate of the second calibration light source 121 based on a second measuring device 102 is obtained. The first measuring device 101 and the second measuring device 102 have a distance D therebetween equal to the predetermined ingot diameter.

In one embodiment, the first measuring device 101 and the second measuring device 102 are parallel to each other, and the line connecting the first measuring device 101 and the second measuring device 102 is parallel to a line connecting the first calibration light source and the second calibration light source.

In one embodiment, the first measuring device 101 is the first CCD camera, the second measuring device is the second CCD camera. The step for obtaining the first coordinate of the first calibration light source 111 by using the first measuring device 101 includes that: the first CCD camera captures the light emitted by the first calibration light source 111, records the coordinate of the first calibration light source 111 as the first coordinate. The step for obtaining the second coordinate of the second calibration light source 121 by using the second measuring device 102 includes that: the second CCD camera captures the light emitted by the second calibration light source 121, records the coordinate of the second calibration light source 121 as the second coordinate.

Then the step S103 is conducted. The diameter measurement coefficient is obtained based on the first coordinate, the second coordinate and the first distance.

In one embodiment, the step S103 comprises: the diameter measurement coefficient is equal to the product of the reciprocal of the absolute value of the difference between the first coordinate and the second coordinate and the first distance.

In one embodiment, since the CCD camera captures the coordinate of the calibration light source, the obtained coordinate needs to be converted to a distance. The diameter measurement coefficient K can be calculated based on the first coordinate X₁, the second coordinate X₂ and the first distance D₁ via the following equation:

$$K = \frac{{D}_{1}}{\vert {X}_{1} - {X}_{2} \vert}$$

In one embodiment, the method further comprises: controlling the first set of the plural sets of the first calibration light source and the second calibration light source to emit light; obtaining a first coordinate of the first calibration light source in the first set based on the first measuring device, and obtaining a second coordinate of the second calibration light source in the first set based on the second measuring device; obtaining a first diameter measurement coefficient based on the first coordinate, the second coordinate, and the first distance between the first calibration light source and the second calibration light source in the first set; controlling a second set of the plural sets of the first calibration light source and the second calibration light source to emit light; obtaining a third coordinate of the first calibration light source in the second set based on the first measuring device, and obtaining a fourth coordinate of the second calibration light source in the second set based on the second measuring device; obtaining a second diameter measurement coefficient based on the third coordinate, the fourth coordinate, and the second distance between the first calibration light source and the second calibration light source in the second set; repeating the above steps to obtain plural diameter measurement coefficients relative to the plural sets of the first calibration light source and the second calibration light source; and obtaining the diameter measurement coefficient based on the plural diameter measurement coefficients.

In one embodiment, the plural diameter measurement coefficients K₁, K₂ . . . Kₙ relative to the plural sets of the first calibration light source and the second calibration light source are obtained. The step for obtaining the diameter measurement coefficient based on the plural diameter measurement coefficients comprises: obtaining an average value of the plural diameter measurement coefficients K₁, K₂ . . . Kₙ via the following equation:

$$K = \frac{1}{n} ( {K}_{1} + {K}_{2} + {K}_{3} + … {K}_{n} )$$

In one embodiment, the plural diameter measurement coefficients K₁, K₂ . . . Kₙ relative to the plural sets of the first calibration light source and the second calibration light source are obtained. The step for obtaining the diameter measurement coefficient based on the plural diameter measurement coefficients comprises that: a median among the plural diameter measurement coefficients K₁, K₂ . . . Kₙ is selected as the diameter measurement coefficient K.

In one embodiment, the plural diameter measurement coefficients K₁, K₂ . . . Kₙ relative to the plural sets of the first calibration light source and the second calibration light source are obtained. The step for obtaining the diameter measurement coefficient based on the plural diameter measurement coefficients comprises: removing one or more of the maximum values and one or more of the minimum values, and obtaining an average value of the remaining plural diameter measurement coefficients as the diameter measurement coefficient K.

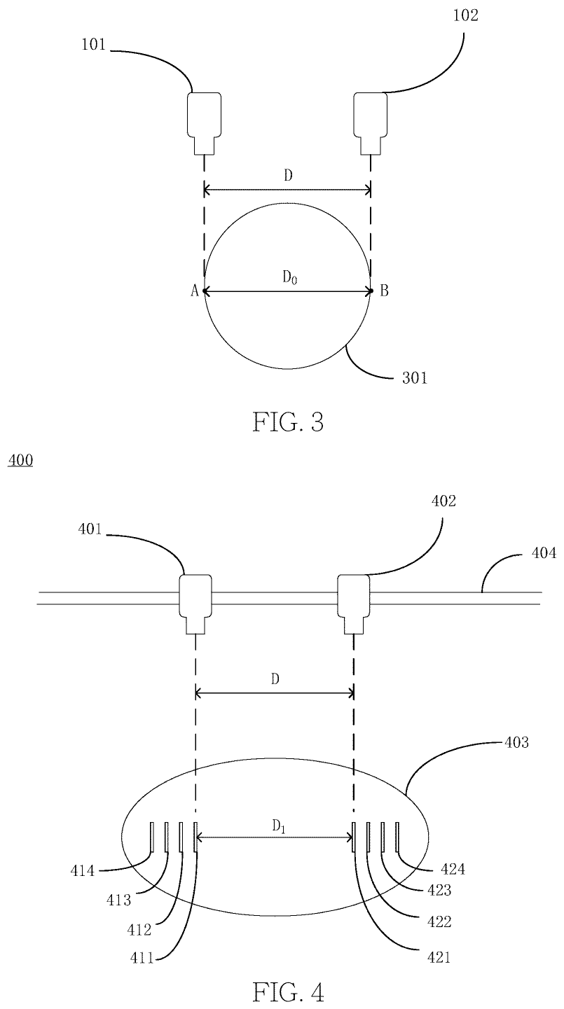

Then the step S104 is conducted. As shown in FIG. 3, during the growth of the crystal ingot 301, a first diameter coordinate X_{A} of one end A of the diameter D₀ of the ingot 301 is obtained by using the first measuring device 101, and a second diameter coordinate X_{B} of the other end B of the diameter D₀ of the ingot 301 is obtained by using the second measuring device 102.

In one embodiment, during the growth of the crystal ingot 301, the first measuring device 101 is a first CCD camera, the second measuring device 102 is a second CCD camera. During the growth of the crystal ingot 301, the first CCD camera and the second CCD camera synchronously record the coordinates of both ends A and B of the diameter D₀ of the ingot 301.

Then the step S105 is conducted. Based on the first diameter coordinate X_{A}, the second diameter coordinate X_{B} and the diameter measurement coefficient K, a measured value of the ingot diameter Dₘ is obtained.

In one embodiment, the measured value of the ingot diameter Dₘ can be obtained based on the first diameter coordinate X_{A}, the second diameter coordinate X_{B} and the diameter measurement coefficient K via the following equation:

$${D}_{m} = K \cdot \vert {X}_{A} - {X}_{B} \vert$$

In one embodiment, the first measuring device 101 and the second measuring device 102 continuously and synchronously obtain plural sets of the first diameter coordinate X_{A} and the second diameter coordinate X_{B} and the diameter measurement coefficient K, such that the diameter of the ingot can be continuously monitored. Thereby, the diameter of the ingot can be controlled and maintained stably during the ingot growth.

In one embodiment, two sets of the measuring devices are applied. The detection direction of the first measuring device is parallel to that of the second measuring device and the space distance between them is equal to a first predetermined distance, such that the first measuring device and the second measuring device face the detection target and maintain a parallel detection direction. Thereby the detection error between the actual value and the measured value can be reduced.

In one embodiment, after the growth of the ingot, the actual diameter measurement coefficient is obtained based on the first diameter coordinate, the second diameter coordinate and the actual value of the ingot diameter. While the difference between the actual diameter measurement coefficient and the diameter measurement coefficient is larger than a predetermined coefficient threshold, the actual diameter measurement coefficient is used to update the diameter measurement coefficient.

In one embodiment, in the step of obtaining an actual diameter measurement coefficient based on the first diameter coordinate, the second diameter coordinate, and the actual value of the ingot diameter, the actual diameter measurement coefficient is equal to the product of the actual value of the ingot diameter and the reciprocal of the absolute value of the difference between the first diameter coordinate and the second diameter coordinate.

In one embodiment, after the completion of the ingot growth, a measuring tool can be used to measure the actual value D* of the diameter of the ingot. Based on the first diameter coordinate X_{A}, the second diameter coordinate X_{B}, and the actual value D* of the ingot diameter, the actual diameter measurement coefficient K* can be obtained via the following equation:

$${K}^{*} = \frac{{D}^{*}}{\vert {X}_{A} - {X}_{B} \vert}$$

In one embodiment, the diameter measurement coefficient K is compared with the actual diameter measurement coefficient K*. While the difference between the actual diameter measurement coefficient and the diameter measurement coefficient is larger than a predetermined coefficient threshold, the actual diameter measurement coefficient K* is used to update the diameter measurement coefficient K, i.e. K=K*.

In the present application, the method for diameter measurement of Czochralski monocrystalline silicon comprises: controlling a first calibration light source and a second calibration light source to emit light; obtaining a first coordinate of the first calibration light source based on a first measuring device, obtaining a second coordinate of the second calibration light source based on a second measuring device; obtaining a diameter measurement coefficient based on the first coordinate, the second coordinate and the first distance; obtaining a first diameter coordinate of one end of the ingot diameter by the first measuring device, and obtaining a second diameter coordinate of another end of the ingot diameter by the second measuring device; and obtaining a measured value of the ingot diameter based on the first diameter coordinate, the second diameter coordinate and the diameter measurement coefficient. Accordingly, the measurement error of the diameter of the Czochralski monocrystalline silicon can be reduced, and the accuracy of ingot diameter control during the growth process can be improved, thereby the production efficiency of Czochralski single crystal silicon can be increased.

In another aspect, the present application provides an apparatus 400 for diameter measurement of Czochralski monocrystalline silicon comprising a first measuring device 401, a second measuring device 402 and a calibration device 403, wherein:
the first measuring device 401 and the second measuring device 402 have a distance D therebetween equal to a predetermined ingot diameter, the first measuring device 401 is to obtain a first coordinate of a first calibration light source 411 of the calibration device 403, and the second measuring device 402 is to obtain a second coordinate of a second calibration light source 421 of the calibration device 403;
the calibration device 403 comprises the first calibration light source 411 and the second calibration light source 421, wherein the first calibration light source 411 and the second calibration light source 421 have a first distance D₁ therebetween, an absolute value of a difference between the first distance D₁ and the predetermined ingot diameter is less than a predetermined threshold, and a line connecting the first calibration light source 411 and the second calibration light source 421 has a midpoint located at center of a cross section perpendicular to axial direction of the ingot during the ingot growth.

In one embodiment, the predetermined threshold ranges from 3% to 6% of the predetermined ingot diameter. The distance between the first calibration light source 411 and the second calibration light source 421 is close to the predetermined ingot diameter. In one embodiment, during the ingot growth, the ingot has a cross section perpendicular to the axial direction of the ingot. The cross section of the ingot has a diameter. In one embodiment, the first calibration light source 411 is located at one end of the diameter of the cross section, and the second calibration light source 421 is located at the other end of the diameter. The first calibration light source 411 and the second calibration light source 421 are applied to simulate the two opposite ends of the diameter of the cross section perpendicular to the axial direction of the ingot during the growth process.

In one embodiment, the diameter measurement apparatus 400 can comprise plural calibration devices 403. In the plural calibration devices 403, the first calibration light source 411 and the second calibration light source 421 may have various distances therebetween corresponding to various predetermined ingot diameters. A suitable calibration device 403 can be selected according to the predetermined ingot diameter.

In one embodiment, the calibration device 403 comprises one set or more sets of the calibration light sources. In one embodiment, one set contains a first calibration light source and a second calibration light source.

In one embodiment, as shown in FIG. 4, the calibration device 403 comprises four sets of the calibration light sources, in which the first set contains the first calibration light source 411 and the second calibration light source 421; the second set contains the first calibration light source 412 and the second calibration light source 422; the third set contains the first calibration light source 413 and the second calibration light source 423; and the fourth set contains the first calibration light source 414 and the second calibration light source 424. In the first set, the first calibration light source 411 and the second calibration light source 421 have a first distance D₁ therebetween. In the second set, the first calibration light source 412 and the second calibration light source 422 have a first distance D₂ therebetween. In the third set, the first calibration light source 413 and the second calibration light source 423 have a first distance D₃ therebetween. In the fourth set, the first calibration light source 414 and the second calibration light source 424 have a first distance D₄ therebetween. The first distance D₁, the second distance D₂, the third distance D₃, and the fourth distance D₄ meet the condition that the absolute value of the difference between the distance and the predetermined ingot diameter is less than a predetermined threshold.

In one embodiment, the first measuring device 401 and the second measuring device 402 are parallel to each other, and the line connecting the first measuring device 401 and the second measuring device 402 is perpendicular to axial direction of the ingot during the ingot growth.

In one embodiment, the first measuring device 401 and the second measuring device 402 comprise CCD camera.

In one embodiment, the shooting directions of the first CCD camera 401 and the second CCD camera 402 are parallel to each other. During the crystal growing, the first CCD camera 401 and the second CCD camera 402 are at an angle perpendicular to the ingot axial direction to capture the image of the ingot. In particular, the first CCD camera 401 shoots one terminal of a diameter of a section of the ingot perpendicular to the ingot axial direction, and the second CCD camera 402 shoots the other terminal of the diameter.

In one embodiment, the diameter measurement apparatus 400 further comprises a guide rail 404. The guide rail 404 is perpendicular to the ingot axial direction. The first measuring device 401 and the second measuring device 402 are mounted on the guide rail. The first measuring device 401 and the second measuring device 402 are movable along the guide rail.

In one embodiment, corresponding to the ingot with various predetermined ingot diameters, the first measuring device 401 and the second measuring device 402 may have various distances therebetween. By moving the first measuring device 401 and the second measuring device 402 along the guide rail, the distance therebetween can be equal to the predetermined ingot diameter.

In the other aspect, the present application provides a device for growing Czochralski monocrystalline silicon ingot comprising a diameter measurement apparatus as any of the previously described.

The foregoing embodiments are descriptions of the present disclosure instead of a limitation on the present disclosure, and a person skilled in the art may design a replacement embodiment without departing from the scope of the accompanying claims. The word “comprise” does not exclude an element or a step not listed in the claims. The word “a” or “one” located previous to an element does not exclude existence of a plurality of such elements. The present disclosure may be implemented by hardware including several different elements and an appropriately programmed computer. Use of the words such as “first”, “second”, and “third” does not indicate any sequence.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure. The scope of the present invention is defined by the appended claims and their equivalent scope.

What is claimed is:

1. A method for diameter measurement of Czochralski monocrystalline silicon comprising:
Step 101: controlling a first calibration light source and a second calibration light source to emit light,
wherein the first calibration light source and the second calibration light source have a first distance therebetween, an absolute value of a difference between the first distance and a predetermined ingot diameter is less than a predetermined threshold, and a line connecting the first calibration light source and the second calibration light source has a midpoint located at center of a cross section perpendicular to axial direction of the ingot during the ingot growth;
Step 102: obtaining a first coordinate of the first calibration light source based on a first measuring device, obtaining a second coordinate of the second calibration light source based on a second measuring device, wherein the first measuring device and the second measuring device have a distance therebetween equal to the predetermined ingot diameter;
Step 103: obtaining a diameter measurement coefficient based on the first coordinate, the second coordinate and the first distance;
Step 104: obtaining a first diameter coordinate of one end of the ingot diameter by the first measuring device, and obtaining a second diameter coordinate of the other end of the ingot diameter by the second measuring device; and
Step 105: obtaining a measured value of the ingot diameter based on the first diameter coordinate, the second diameter coordinate and the diameter measurement coefficient.

2. The method of claim 1, further comprising: setting one or plural sets of the first calibration light source and the second calibration light source, and obtaining the diameter measurement coefficient based on the one or plural sets of the first calibration light source and the second calibration light source.

3. The method of claim 2, further comprising:
controlling a first set of the plural sets of the first calibration light source and the second calibration light source to emit light;
obtaining a first coordinate of the first calibration light source in the first set based on the first measuring device, and obtaining a second coordinate of the second calibration light source in the first set based on the second measuring device;
obtaining a first diameter measurement coefficient based on the first coordinate, the second coordinate, and the first distance between the first calibration light source and the second calibration light source in the first set;
controlling a second set of the plural sets of the first calibration light source and the second calibration light source to emit light;
obtaining a third coordinate of the first calibration light source in the second set based on the first measuring device, and obtaining a fourth coordinate of the second calibration light source in the second set based on the second measuring device;
obtaining a second diameter measurement coefficient based on the third coordinate, the fourth coordinate, and a second distance between the first calibration light source and the second calibration light source in the second set;
repeating the above steps to obtain plural diameter measurement coefficients relative to the plural sets of the first calibration light source and the second calibration light source; and
obtaining the diameter measurement coefficient based on the plural diameter measurement coefficients.

4. The method of claim 1, wherein, in the Step 103, the diameter measurement coefficient is equal to the product of the first distance and the reciprocal of the absolute value of the difference between the first coordinate and the second coordinate.

5. The method of claim 1, wherein, in the Step 105, the measured value of the ingot diameter is equal to the product of the diameter measurement coefficient and the absolute value of the difference between the first diameter coordinate and the second diameter coordinate.

6. The method of claim 1, further comprising:
obtaining an actual value of the ingot diameter after the ingot growth;
obtaining an actual diameter measurement coefficient based on the first diameter coordinate, the second diameter coordinate, and the actual value of the ingot diameter; and
while a difference between the actual diameter measurement coefficient and the diameter measurement coefficient obtained from the Step 103 is more than the predetermined coefficient threshold, applying the actual diameter measurement coefficient to update the diameter measurement coefficient.

7. The method of claim 6, wherein, in the step of obtaining an actual diameter measurement coefficient based on the first diameter coordinate, the second diameter coordinate, and the actual value of the ingot diameter, the actual diameter measurement coefficient is equal to the product of the actual value of the ingot diameter and the reciprocal of the absolute value of the difference between the first diameter coordinate and the second diameter coordinate.

8. An apparatus for diameter measurement of Czochralski monocrystalline silicon comprising a first measuring device, a second measuring device and a calibration device, wherein
the first measuring device and the second measuring device have a distance therebetween equal to a predetermined ingot diameter, the first measuring device is to obtain a first coordinate of a first calibration light source of the calibration device, and the second measuring device is to obtain a second coordinate of a second calibration light source of the calibration device;
the calibration device comprises the first calibration light source and the second calibration light source, wherein the first calibration light source and the second calibration light source have a first distance therebetween, an absolute value of a difference between the first distance and the predetermined ingot diameter is less than a predetermined threshold, and a line connecting the first calibration light source and the second calibration light source has a midpoint located at center of a cross section perpendicular to axial direction of the ingot during the ingot growth.

9. The apparatus of claim 8, wherein the first measuring device has a measuring direction parallel to that of the second measuring device, and the line connecting the first measuring device and the second measuring device is perpendicular to axial direction of the ingot during the ingot growth.

10. The apparatus of claim 8, further comprising a guide rail, wherein the guide rail is perpendicular to the axial direction of the ingot during the ingot growth, the first measuring device and the second measuring device are arranged on and movable along the guide rail.

11. The apparatus of claim 8, wherein the first measuring device and the second measuring device comprise a charge coupled device (CCD) camera.

12. The apparatus of claim 8, wherein the calibration device comprises one or plural sets of the first calibration light source and the second calibration light source.

13. A device for growing Czochralski monocrystalline silicon comprising an apparatus of claim 8.
